(19) United States
(12) Patent Application Publication
(10) Pub. No.: US 2018/0113152 A1
(43) Pub. Date: Apr. 26, 2018

(54) ANISOTROPIC CONDUCTIVE SHEET, ELECTRICAL INSPECTION HEAD, ELECTRICAL INSPECTION DEVICE, AND METHOD FOR MANUFACTURING AN ANISOTROPIC CONDUCTIVE SHEET

(71) Applicant: Yamaha Fine Technologies Co.,Ltd., Hamamatsu Shizuoka (JP)

(72) Inventors: Katsunori SUZUKI, Hamamatsu (JP); Yasuro OKUMIYA, Mori-machi (JP); Makoto TERAOKA, Hamamatsu (JP); Satoshi YAMAMOTO, Hamamatsu (JP)

(21) Appl. No.: 15/787,121

(22) Filed: Oct. 18, 2017

(30) Foreign Application Priority Data
Oct. 20, 2016 (JP) 2016-206201

(51) Int. Cl. G01R 1/067; G01R 31/28; H01B 1/24

(52) U.S. Cl. CPC G01R 1/06733; H01B 1/24; G01R 31/2805; G01R 1/06761

(57) ABSTRACT

An anisotropic conductive sheet, in which the arrangement interval of the structure that exhibits conductivity in a planar section is relatively small, comprises an elastic layer having resin as the main component, and a plurality of CNT pillars that are formed from CNT fiber bundles and penetrate the elastic layer in the thickness direction. The electrical inspection head measures electrical characteristics between a plurality of measurement points of a measurement target, and comprises a measurement substrate having a plurality of electrode pads on its surface that opposes the measurement points, and an anisotropic conductive sheet laminated on that surface. The method for manufacturing an anisotropic conductive sheet comprises growing a plurality of CNT pillars formed from CNT fiber bundles by chemical vapor deposition by arranging catalysts on the surface of a growth substrate, and filling the space between the plurality of CNT pillars with a resin composition.

### CROSS-REFERENCE TO RELATED APPLICATION

This application claims the benefit of Japanese Patent Application No. 2016-206201, filed on Oct. 20, 2016, the entire contents of Japanese Patent Application No. 2016-206201 being incorporated herein by reference.

### BACKGROUND

### Field of the Invention

The present invention relates to an anisotropic conductive sheet, an electrical inspection head, an electrical inspection device, and a method for manufacturing an anisotropic conductive sheet.

### Description of the Related Art

An anisotropic conductive sheet (anisotropic conductive film) that is formed into a sheet shape, exhibits conductivity only in the thickness direction, and that has insulating properties in the planar direction is known. Such anisotropic conductive sheets are used to connect between a glass substrate and a flexible printed-circuit board and to mount electronic components and the like on a substrate.

An anisotropic conductive sheet, in which a plurality of metal wires oriented in the thickness direction and disposed in an insulating sheet exhibiting elasticity, has been proposed as a specific configuration example thereof (refer to Japanese Laid-Open Patent Application No. 2012-022828). Further, the publication described above proposes forming metal wires from a ferromagnetic material, molding the metal wires in a sheet shape, and orienting the metal wires in the thickness direction while applying a magnetic field in the thickness direction of the molding die, thereby imparting anisotropy relatively accurately.

In the method for manufacturing an anisotropic conductive sheet disclosed in the publication described above, metal wires are disposed between electrodes that apply a magnetic field to a molding die. Consequently, in the configuration disclosed in the above-described publication, while it is necessary to reduce the pitch of the electrodes in order to reduce the arrangement interval of the metal wires in a planar section, it is not a simple matter to reduce the pitch of the electrodes, and it is therefore difficult to arrange the metal wires with high density.

However, in recent years, high-density wiring of printed-circuit boards and high integration levels of electronic components have been in progress, and there is a demand for a reduction in the arrangement interval, in a planar section, of conductors that impart conductivity to anisotropic conductive sheets.

In addition, using an anisotropic conductive sheet as a probe (contact) of an electrical inspection device that measures electrical characteristics between a plurality of measurement points of a measurement target such as a printed-circuit board has been proposed (refer to Japanese Laid-Open Patent Application No. 2004-333410). In this manner, there is a demand for a reduction in the conductive member repetition interval of an anisotropic conductive sheet, in accordance with a reduction in the interval of measurement points accompanying the high-density wiring of inspection targets, even when using an anisotropic conductive sheet as a probe in an electrical inspection device.

### SUMMARY

In view of the disadvantages described above, an object of the present invention is to provide an anisotropic conductive sheet in which the arrangement interval of the structure that exhibits conductivity in a planar section is relatively small, an electrical inspection head, an electrical inspection device, and a method for manufacturing an anisotropic conductive sheet.

An invention realized in order to achieve the object above is an anisotropic conductive sheet comprising an elastic layer mainly consisting of resin, and a plurality of CNT pillars that are formed from CNT (carbon nanotube) fiber bundles, and that penetrate the elastic layer in the thickness direction. The type A durometer hardness of the elastic layer is preferably 40 or more and 80 or less. It is preferable for the plurality of CNT pillars to have a metal portion forming the end surface thereof, and for at least the metal portion to protrude from the elastic layer.

Additionally, another invention realized to achieve the object above is an electrical inspection head that measures electrical characteristics between a plurality of measurement points of a measurement target, comprising a measurement substrate having a plurality of electrode pads on a surface that opposes the measurement points of the measurement target, and the anisotropic conductive sheet laminated on a surface of the measurement substrate that opposes the measurement target.

Further, another invention realized to achieve the object above is an electrical inspection device comprising the electrical inspection head, and a drive mechanism that relatively positions the electrical inspection head with respect to the measurement target.

In addition, another invention realized in order to achieve the object above is a method for manufacturing an anisotropic conductive sheet, comprising a step to grow a plurality of CNT pillars formed from CNT fiber bundles by a chemical vapor deposition method by arranging a catalyst on the surface of a growth substrate and a step to fill the space between the plurality of CNT pillars with a resin composition.

The method for manufacturing an anisotropic conductive sheet preferably further comprises a step to remove at least one surface layer of the elastic layer formed from the resin composition. The method for manufacturing an anisotropic conductive sheet preferably further comprises a step to heat-treat the plurality of CNT pillars. “Main component” means the component with the greatest mass content. “Type A durometer hardness” is a value that is measured in compliance with JIS-K6253-3 (2012).

The anisotropic conductive sheet of the present invention comprises a plurality of CNT pillars that penetrate the elastic layer in the thickness direction, and the plurality of CNT pillars can be formed in a shape arranged at relatively small intervals by a chemical vapor deposition method in which a catalyst is disposed on the surface of a growth substrate. Thus, in the anisotropic conductive sheet, it is possible to make the arrangement interval in a planar section of the plurality of CNT pillars, which exhibit conductivity, relatively small.

In addition, in the method for manufacturing an anisotropic conductive sheet of the present invention, it is possible to manufacture an anisotropic conductive sheet, in which a plurality of CNT pillars, which exhibit conductivity in the thickness direction, are arranged at relatively small intervals in a planar section, by comprising a step to grow a plurality of CNT pillars formed from CNT fiber bundles by a chemical vapor deposition method by arranging catalysts on the surface of a growth substrate and a step to fill the space between the plurality of CNT pillars with a resin composition.

### BRIEF DESCRIPTION OF THE DRAWINGS

Referring now to the attached drawings which form a part of this original disclosure:

FIG. 1 is a schematic cross-sectional view illustrating the anisotropic conductive sheet according to one embodiment of the present invention;

FIG. 2 is a flowchart illustrating the steps of the method for manufacturing an anisotropic conductive sheet of FIG. 1;

FIG. 3 is a schematic cross-sectional view illustrating one step of the method for manufacturing an anisotropic conductive sheet of FIG. 1;

FIG. 4 is a schematic cross-sectional view illustrating the step after the step of FIG. 3 of the method for manufacturing an anisotropic conductive sheet of FIG. 1;

FIG. 5 is a schematic cross-sectional view illustrating the step after the step of FIG. 4 of the method for manufacturing an anisotropic conductive sheet of FIG. 1;

FIG. 6 is a schematic cross-sectional view illustrating the step after the step of FIG. 5 of the method for manufacturing an anisotropic conductive sheet of FIG. 1;

FIG. 7 is a schematic cross-sectional view illustrating the step after the step of FIG. 6 of the method for manufacturing an anisotropic conductive sheet of FIG. 1;

FIG. 8 is a schematic view of an electrical inspection device comprising the anisotropic conductive sheet of FIG. 1; and

FIG. 9 is a schematic cross-sectional view illustrating the detailed configuration of the electrical inspection head of the electrical inspection device of FIG. 8.

It should be noted that these figures are intended to illustrate the general characteristics of methods and structure utilized in the illustrative embodiment and to supplement the written description provided below. These drawings may not precisely reflect the precise structural or performance characteristics of any given embodiment, and should not be interpreted as defining or limiting the range of values or properties encompassed by illustrative embodiments unless specified.

### DETAILED DESCRIPTION OF EMBODIMENTS

Selected embodiments will now be explained with reference to the drawings. It will be apparent to those skilled in the music field from this disclosure that the following descriptions of the embodiments are provided for illustration only and not for the purpose of limiting the invention as defined by the appended claims and their equivalents. Like reference numerals in the drawings denote like similar or identical elements or features, and thus the descriptions of the similar or identical elements or features may be omitted in later embodiments.

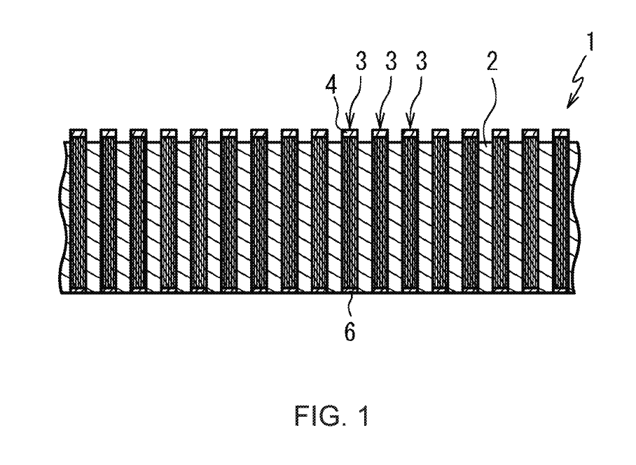

The anisotropic conductive sheet according to one embodiment of the present invention illustrated in FIG. 1 comprises an elastic layer 2 having resin as the main component and a plurality of CNT pillars 3, which are formed from CNT fiber bundles, and that penetrate the elastic layer 2 in the thickness direction.

Elastic Layer

The elastic layer 2 is a structural member that defines the sheet-like shape of the anisotropic conductive sheet 1. The elastic layer 2 is preferably formed from an elastomer that has resin as the main component.

In addition, when using the anisotropic conductive sheet 1 for electrical connections, the elastic layer 2 is preferably formed from a material that is cured and shrunk by heating. By thermally shrinking the elastic layer 2, the thickness of the elastic layer 2 is reduced, causing both ends of the CNT pillars 3 to protrude, and the electrical connections are made more reliable.

The elastomer for forming the elastic layer 2 may be a thermoplastic elastomer, but a thermosetting elastomer is preferably used. By forming the elastic layer 2 from a thermosetting elastomer, it is possible to form relatively easily an elastic layer 2 that has the desired hardness by filling the space between the plurality of CNT pillars 3 with the thermosetting elastomer and then curing.

Examples of thermoplastic elastomers include styrene type elastomers (SBC), olefin type elastomers (TPO), vinyl chloride type elastomers (TPVC), urethane type elastomers (PU), ester type elastomers (TPEE), and amide type elastomers (TPAE).

Examples of thermosetting elastomers include natural rubber (NR), butyl rubber (IIR), isoprene rubber (IR), ethylene/propylene rubber (EPDM), butadiene rubber (BR), urethane rubber (U), styrene/butadiene rubber (SBR), silicone rubber (Q), chloroprene rubber (CR), chlorosulfonated polyethylene rubber (CSM), acrylonitrile butadiene rubber (NBR), chlorinated polyethylene (CM), acrylic rubber (ACM), epichlorohydrin rubber (CO, ECO), fluororubber (FKM), and polydimethylsiloxane (PDMS). Of the above, silicone rubber, which has excellent electrical insulating properties, low dielectric properties, and chemical stability, is particularly preferable.

Additionally, the elastic layer 2 may include an inorganic filler to reduce the dielectric loss tangent. In this manner, by reducing the dielectric loss tangent of the elastic layer 2 with an inorganic filler, the signal transmission characteristic is improved when transmitting high frequency signals via the anisotropic conductive sheet 1.

The lower limit of the type A durometer hardness of the elastic layer 2 is preferably 40, and more preferably 50. On the other hand, the upper limit of the type A durometer hardness of the elastic layer 2 is preferably 80, and more preferably 70. If the type A durometer hardness of the elastic layer 2 is less than the above-described lower limit, there is the risk that the strength of the anisotropic conductive sheet 1 will be insufficient. On the other hand, if the type A durometer hardness of the elastic layer 2 exceeds the above-described upper limit, there is the risk that the CNT pillars will not be able to be brought into pressure contact with the conductive contact target and that the electrical connection will be insufficient.

The lower limit of the average thickness of the elastic layer 2 is preferably 100 μm, and more preferably 200 μm. On the other hand, the upper limit of the average thickness of the elastic layer 2 is preferably 1000 μm, and more preferably 500 μm. If the average thickness of the elastic layer 2 is less than the above-described lower limit, there is the risk that the strength of the anisotropic conductive sheet 1 will be insufficient. On the other hand, if the average thickness of the elastic layer 2 exceeds the above-described upper limit, there is the risk that the anisotropic conductive sheet 1 will be unnecessarily costly, since it becomes difficult to form the elastic layer 2 while keeping the plurality of CNT pillars 3 parallel to each other.

CNT Pillar

The CNT pillar 3 is made of a columnar body by bundling a plurality of CNT fibers. The CNT pillar 3 is mainly made of CNT fibers and may contain carbon in the form of amorphous carbon or the like.

Either single-layered single-walled nanotubes (SWNT) or multilayered multi-walled nanotubes (MWNT) may be used as the CNT fiber described above. Of the foregoing, MWNT is preferable for possession of excellent conductivity and strength, and MWNT having a diameter of 1.5 nm or more and 100 nm or less is more preferable.

The plurality of CNT pillars 3 may be disposed at random in a planar section, but are preferably disposed in a regular arrangement. Examples of such arrangements of the plurality of CNT pillars 3 include an orthogonal arrangement in which the pillars are arranged vertically and horizontally at equal intervals (on lattice points), and an equiangular triaxial arrangement in which six CNT pillars 3 are arranged at regular intervals every 60°, centered around one CNT pillar 3. In each of the CNT pillars 3, the end surface thereof may be flush with the surface of the elastic layer 2, but preferably protrudes from at least one face of the elastic layer 2, in order to ensure electrical contact with the conductive contact target.

The lower limit of the mean protrusion height of the CNT pillars 3 (mean minimum protrusion height of the CNT pillars 3) from the elastic layer 2 is preferably 5 μm, and more preferably 10 μm. On the other hand, the upper limit of the average protrusion height of the CNT pillars 3 from the elastic layer 2 is preferably 100 μm, and more preferably 50 μm. If the average protrusion height of the CNT pillars 3 from the elastic layer 2 is less than the above-described lower limit, there is the risk that electrical contact with the conductive contact target will be insufficiently promoted. On the other hand, if the average protrusion height of the CNT pillars 3 from the elastic layer 2 exceeds the above-described upper limit, there is the risk that the tips of the CNT pillars 3 will be broken or that the conductive contact target will be unnecessarily damaged.

In addition, each CNT pillar 3 has a metal portion 4 that forms at least one end surface thereof, and it is preferable for at least this metal portion 4 to protrude from the elastic layer 2. Specifically, the metal portion 4 can be formed by exposing or protruding and end portion of the CNT pillar 3 from the elastic layer 2, and disposing metal on the end portion of the CNT pillar 3 that is exposed or protruding from the elastic layer 2. In this manner, by having a metal portion 4 at the end portion of the CNT pillar 3, it becomes possible to destroy the oxide film or the like on the surface of the conductive contact target in order to achieve a more reliable electrical contact. Examples of the main component of this metal portion 4 include iron, gold, copper, nickel, and tin, as well as alloys thereof.

In addition, by forming the metal portion 4 with a solder, it is possible to impart mechanical connectivity to each of the CNT pillars 3. That is, it is possible to electrically and mechanically connect the anisotropic conductive sheet to the conductive contact target by reflow of the metal portion 4 formed from a solder.

The lower limit of the average diameter of the CNT pillars 3 is preferably 1 μm, and more preferably 2 μm. On the other hand, the upper limit of the average diameter of the CNT pillars 3 is preferably 15 μm, and more preferably 10 μm. If the average diameter of the CNT pillars 3 is less than the above-described lower limit, there is the risk that it will be difficult to realize uniform manufacturing of the CNT pillars 3, or that the CNT pillars 3 will have insufficient rigidity, and that the electrical contact with respect to the conductive contact target will tend to be insufficient. On the other hand, if the average diameter of the CNT pillars 3 exceeds the above-described upper limit, there is the risk that it will also be difficult to realize uniform manufacturing of the CNT pillars 3, or that the arrangement interval of the CNT pillars 3 in a planar section will not be able to be sufficiently reduced. Here, “average diameter” means the circle equivalent diameter (diameter of a circle having the same area as the cross-sectional area).

The lower limit of the average interval of the plurality of CNT pillars 3 is preferably 2 μm, and more preferably 3 μm. On the other hand, the upper limit of the average interval of the plurality of CNT pillars 3 is preferably 100 μm, and more preferably 10 μm. If the average interval of the plurality of CNT pillars 3 is less than the above-described lower limit, there is the risk the CNT pillar3 will come in contact with each other, and that the anisotropic conductivity of the anisotropic conductive sheet 1 will be insufficient. On the other hand, if the average interval of the plurality of CNT pillars 3 exceeds the above-described upper limit, since the pitch of the CNT pillars 3, which exhibit conductivity, is narrow, there is the risk that the range of utilization of the anisotropic conductive sheet 1 will be limited.

Method for Manufacturing an Anisotropic Conductive Sheet

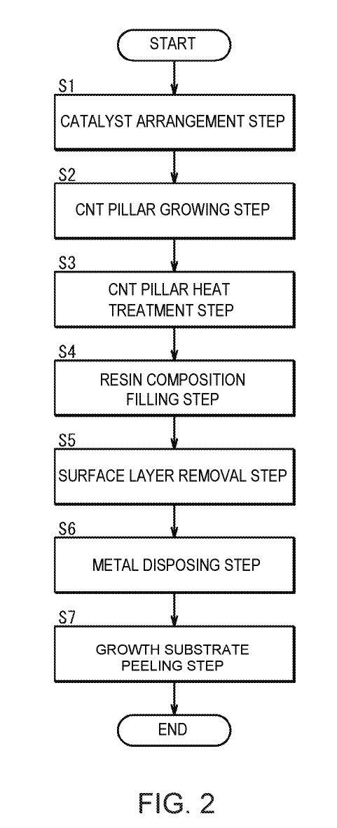

As shown in FIG. 2, the anisotropic conductive sheet 1 can be manufactured with a manufacturing method that comprises a step to arrange a catalyst on the surface of a growth substrate <Step S1: catalyst arrangement step>, a step to grow a plurality of CNT pillars on the surface of the growth substrate by a chemical vapor deposition method (Step S2: CNT pillar growing step>, a step to heat-treat the plurality of CNT pillars <Step S3: CNT pillar heat treatment step>, a step to fill the space between the plurality of CNT pillars with a resin composition <Step S4: resin composition filling step>, a step to remove at least one surface layer of the elastic layer formed from the resin composition <Step S5: surface layer removal step>, a step to dispose metal at an end portion of the CNT pillar that protrudes from the elastic layer <Step S6: metal disposing step>, and a step to peel off the growth substrate <Step S7: growth substrate peeling step>.

Catalyst Arrangement Step

In the catalyst arrangement step of Step S1, as shown in FIG. 3, a catalyst 6 is disposed on the surface of the growth substrate 5. Examples of methods to dispose the catalyst 6 include techniques such as printing, plating, sputtering, and dipping. At this time, a mask, which is open in the areas where the catalyst 6 should be arranged, may be used in order to form the catalyst 6 in a planar pattern that has the desired arrangement.

Examples of the growth substrate 5 that can be used include a plate-like body or a sheet-like body, formed from stainless steel, on the surface of which is formed an alumina buffer layer, silicon with oxide film, ceramic, or the like. Examples of the catalyst 6 include iron, nickel, cobalt, titanium, and platinum.

CNT Pillar Growing Step

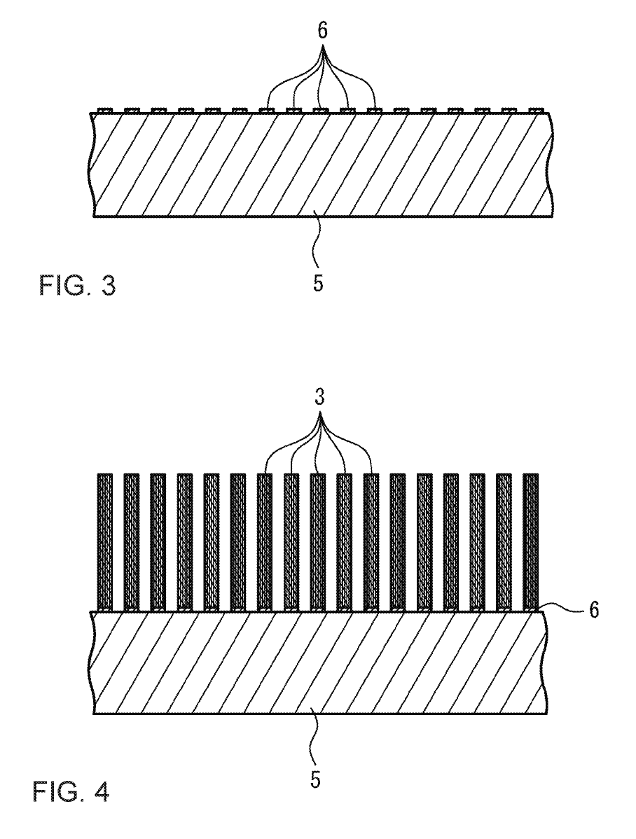

In the CNT pillar growing step of Step S2, the growth substrate 5, on the surface of which are arranged the catalyst 6, is disposed inside a sealed reaction tube, and raw material gas is supplied into the reaction tube to continuously produce and grow carbon nanotubes by a catalytic reaction and to thereby form a plurality of CNT pillars 3. As shown in FIG. 4, it is thus possible to form a plurality of CNT pillars 3 that are vertically erected on the surface of the growth substrate 5.

Examples of the raw material gas described above include organic compounds such as acetylene (C₂H₂) and methane (C₂H₄), of which acetylene is more preferable. By using acetylene as the raw material gas, pyrolysis reaction can be continued spontaneously without using a combustion-assisting gas, such as oxygen; therefore, carbon nanotubes can be stably and safely grown.

The rate of the reaction for producing CNT can be adjusted by the supply amount of the raw material gas. If the reaction rate becomes excessive, there is the risk that amorphous carbon will be deposited on the growth substrate 5 to inhibit the catalytic reaction. The raw material gas may be diluted and supplied by mixing a carrier gas therewith in order to control the reaction rate. Examples of the carrier gas that can be used include nitrogen (N₂) and hydrogen (H₂).

CNT Pillar Heat Treatment Step

In the CNT pillar heat treatment step of Step S3, the growth substrate 5, on which a plurality of CNT pillars 3 are formed, is heated to heat-treat the CNT pillars 3, to thereby increase the rigidity of the CNT pillars 3. The lower limit of the heat treatment temperature is preferably 500° C., and more preferably 800° C. The upper limit of the heat treatment temperature is preferably 1200° C., and more preferably 1000° C. If the heat treatment temperature is less than the above-described lower limit, there is the risk that the rigidity of the CNT pillars 3 cannot be increased. On the other hand, if the heat treatment temperature exceeds the above-described upper limit, there is the risk that the CNT pillars 3 will become brittle and prone to breakage.

The lower limit of the heat treatment time (the time that the heat treatment temperature is maintained) is preferably five minutes, and more preferably ten minutes. On the other hand, the upper limit of the heat treatment time is preferably 60 minutes, and more preferably 30 minutes. If the heat treatment time is less than the above-described lower limit, there is the risk that the heat treatment of the CNT pillars 3 will be insufficient. On the other hand, if the heat treatment time exceeds the above-described upper limit, there is the risk that the CNT pillars 3 will become brittle or that the manufacturing cost of the anisotropic conductive sheet will be unnecessarily increased.

Resin Composition Filling Step

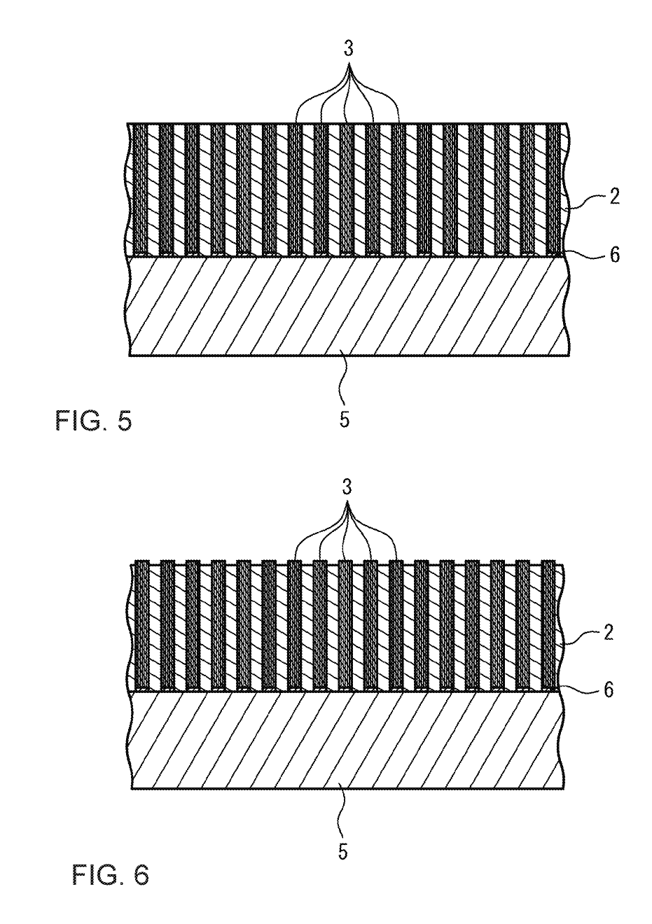

In the resin composition filling step of Step S4, as shown in FIG. 5, the surface of the growth substrate 5 is filled with a resin composition and cured, to thereby form an elastic layer 2. This resin composition filling step is preferably carried out by disposing the growth substrate 5, on which a plurality of CNT pillars 3 are formed, in a molding die.

The resin composition preferably has a sufficiently small viscosity at the time of filling. Thus, the resin composition that is filled in the resin composition filling step is preferably obtained by adding a polymerization initiator to a monomer or a prepolymer, which becomes the elastomer that forms the elastic layer 2 by polymerization. Additionally, in the resin composition filling step, a treatment such as heating, irradiating energy rays (electromagnetic waves) such as light, or humidifying may be carried out, in order to promote the curing (polymerization) of the resin composition after the filling of the resin composition.

Surface Layer Removal Step

In the surface layer removal step of Step S5, as shown in FIG. 6, the tip portion of the CNT pillar 3 is exposed by removing the surface layer of the elastic layer 2 on the opposite side of the growth substrate 5. Examples of methods for removing the surface layer of the elastic layer 2 that can be employed include ashing (a resist peeling technique, such as photoexcitation ashing and plasma ashing) and etching.

Metal Disposing Step

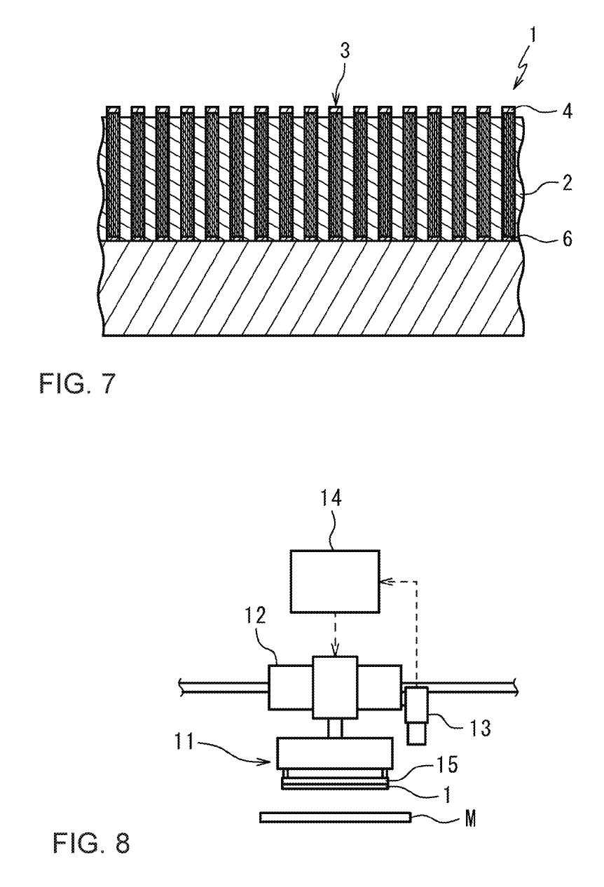

In the metal disposing step of Step S6, as shown in FIG. 7, a metal portion 4 is provided to the tip of the CNT pillar 3 that projects from the elastic layer 2. Examples of methods to dispose the metal portion 4 include plating, dipping in a metal melt, and vapor deposition.

Growth Substrate Peeling Step

In the growth substrate peeling step of Step S7, the growth substrate 5 is peeled off to thereby obtain the anisotropic conductive sheet 1.

Benefits

Since the anisotropic conductive sheet 1 exhibits conductivity in the thickness direction of the elastic layer 2 by the plurality of CNT pillars 3, it is possible to arrange the plurality of CNT pillars 3 at a relatively small interval. As a result, the anisotropic conductive sheet 1 is able to selectively exhibit conductivity with a relatively fine planar pattern. In addition, the anisotropic conductive sheet 1 is able to carry out an electrical connection with a relatively low pressure compared with a conventional anisotropic conductive film, without the application of pressure in the thickness direction, since the plurality of CNT pillars 3 have conductivity in the thickness direction; therefore, various electronic devices can be easily and inexpensively produced.

Electrical Inspection Device

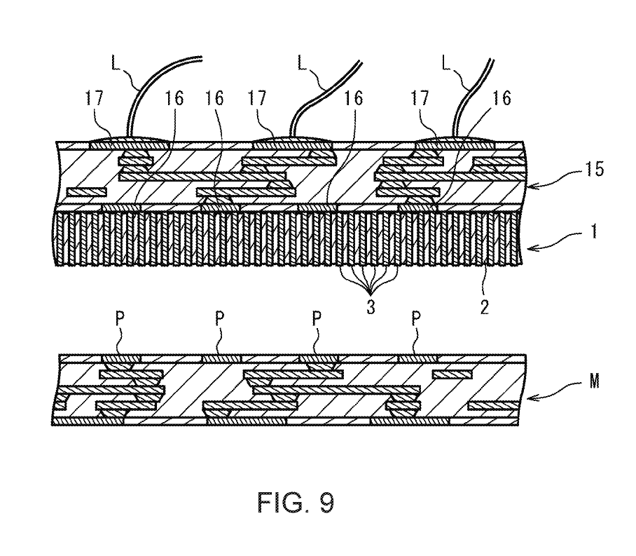

FIG. 8 illustrates a schematic configuration of an electrical inspection device, which comprises the anisotropic conductive sheet of FIG. 1, and which is itself one embodiment of the present invention. The electrical inspection device is a device for inspecting the electric characteristics between a plurality of measurement points P (refer to FIG. 9) on the surface of a measurement target M.

The electrical inspection device comprises an electrical inspection head 11 that is pressed against the surface of the measurement target M, a head drive mechanism 12 that drives the electrical inspection head 11, an image processing device 13 that acquires position information of the measurement target M, and a controller 14 that controls the head drive mechanism 12 based on the position information acquired from the image processing device 13. The electrical inspection device may further comprise a platen on which the measurement target M is placed, a holding mechanism that holds the outer edge portion of the measurement target M, a frame that holds each of the compositional elements, and the like.

Measurement Target

Examples of measurement targets M the electric characteristics of which are inspected by the electrical inspection device include electronic components such as an IC and printed-circuit boards. An example of a measurement point P when the measurement target M is an IC is a pad electrode. In addition, examples of measurement points P when the measurement target M is a printed-circuit board include measuring lands provided in the conductive pattern and lands for component mounting.

Electrical Inspection Head

The electrical inspection head 11 is itself one embodiment of the present invention. The electrical inspection head 11 comprises a measurement substrate 15 that is to be held parallel to the measurement target M, and the anisotropic conductive sheet 1 of FIG. 1 laminated on a surface of this measurement substrate 15 that opposes the measurement target M.

Measurement Substrate

As shown in FIG. 9, a plurality of electrode pads 16 that oppose the measurement points P of the measurement target M are arranged on the surface of the measurement substrate 15 that opposes the measurement target M. In addition, a plurality of relay electrodes 17, to which wiring L that connects to a measurement circuit, not shown in the figures, is provided on the surface of the measurement substrate 15 on the opposite side of the measurement target M. The measurement substrate 15 is a multilayer printed-circuit board that connects a plurality of electrode pads 16 to a plurality of relay electrodes 17. The plurality of electrode pads 16 and the plurality of relay electrodes 17 do not necessarily correspond to each other one-to-one; for example, a plurality of electrode pads may be connected to one relay electrode 17 that is connected to ground.

With such a measurement substrate 15, it is possible to make the size and the interval of the electrode pads 16 smaller than the size and interval of the relay electrodes 17. Thus, the electrical inspection device is able to inspect the electrical characteristics of a measurement target M in which the interval between the measurement points P is relatively small.

The size and shape of the electrode pads 16 of the measurement substrate 15 are preferably the same as the size and shape of the measurement points P of the measurement target M. In other words, the plurality of electrode pads 16 of the measurement substrate 15 are preferably formed in a mirror image of the plurality of measurement points P of the measurement target M.

Anisotropic Conductive Sheet

In the electrical inspection head 11, the anisotropic conductive sheet 1 is used as a probe that is made to come in electrical contact with the measurement target M and is used as a probe assembly in which the plurality of CNT pillars 3 is held by the elastic layer 2. The anisotropic conductive sheet 1 is held such that the side of the CNT pillar 3 that has the metal portion 4 faces the measurement target M. The anisotropic conductive sheet 1 can be attached to the measurement substrate 15 using an adhesive or the like in an area where an electrode pad 16 does not exist.

Head Drive Mechanism

The head drive mechanism 12 may be any mechanism that can carry out three-dimensional positioning of the electrical inspection head 11, and is preferably a mechanism that can also carry out rotational positioning of the electrical inspection head 11 about the normal direction axis of the measurement target M. While a multi-joint robot may be used as the head drive mechanism 12, it is preferable to employ an orthogonal coordinate type drive system, whose cost and occupying footprint are relatively small. The orthogonal coordinate type drive system may be configured to comprise an orthogonal coordinate type robot that is capable of biaxial positioning of the measurement target M in the planar direction, a lifting device that is disposed at the end of this orthogonal coordinate type robot, and a rotational positioning device that is held by the lifting device so as be vertically movable, and that holds the electrical inspection head so as to be capable of rotational positioning.

Image Processing Device

A well-known device, comprising a camera for capturing digital images and a processing unit for processing the digital images captured by this camera, can be used as the image processing device 13. The processing unit of the image processing device 13 may be integrally formed with a controller 14, described below. That is, the processing unit of the image processing device 13 may be a part of a program that is processed by a computer that constitutes the controller 14. The camera of the image processing device 13 may be independently held, but is preferably held by the head drive mechanism 12 so as to be movable in at least in the plane of the measurement target M, together with the electrical inspection head 11.

Controller

The controller 14 acquires position information by means of the image processing device 13 and controls the positioning of the electrical inspection head 11 with respect to the measurement target M by means of the head drive mechanism 12. Examples of this controller 14 include a programmable logic controller, a personal computer, and the like.

Benefits

In the electrical inspection device comprising the electrical inspection head 11, the size and the intervals of the CNT pillars 3 of the anisotropic conductive sheet 1 in a planar section can be made remarkably smaller than the size and the interval of the measurement points P of the measurement target M and the electrode pads 16 of the measurement substrate 15. Therefore, in the electrical inspection device that uses the electrical inspection head 11, it is possible to form reliable electrical connections between the measurement point P of the measurement target M and the electrode pads 16 of the measurement substrate 15 by means of the plurality of CNT pillars 3. On the other hand, since the area of the CNT pillars 3 in the planar direction is extremely small, short-circuiting will not be caused between adjacent measurement points P, or between a measurement point P and an electrode pad 16 that do not face each other.

Additionally, if electrical inspection is carried out on a large number of measurement targets M using the electrical inspection device comprising the electrical inspection head 11, the CNT pillars 3 of the anisotropic conductive sheet 1 that are used as a probe assembly will become worn. Since the configuration of the anisotropic conductive sheet 1 is not dependent on the arrangement of the measurement points P of the measurement target M in the electrical inspection device, it is possible to replace only the provided anisotropic conductive sheet 1 relatively inexpensively and to continue using the relatively expensive electrical inspection head 11.

### Other Embodiments

The above-described embodiment does not limit the configuration of the present invention. Therefore, in the above-described embodiment, the compositional elements of each part of the embodiment may be omitted, replaced, or added based on the recitation of the present Specification and common knowledge in the art, all of which shall be interpreted as belonging to the scope of the present invention.

The elastic layer of the anisotropic conductive sheet may have a multilayer structure. For example, adhesiveness can be imparted to the anisotropic conductive sheet by using a material exhibiting adhesiveness on the surface layer of the elastic layer.

In the method for manufacturing an anisotropic conductive sheet, the surface layer removal step and the metal disposing step are not essential. That is, the CNT pillars of the anisotropic conductive sheet need only be exposed from the elastic layer, and need not protrude from the elastic layer. Furthermore, it is not necessary that tips of the CNT pillar of the anisotropic conductive sheet be provided with metal.

In the surface layer removal step in the method for manufacturing an anisotropic conductive sheet, the surface layer may be unevenly removed so that the thickness of the elastic layer changes continuously. As a specific example, a convex surface or a concave surface, in which the thickness of the central portion and the outer edge portion differ, may be formed such that the thickness of the elastic layer is decreased in one direction. In the anisotropic conductive sheet, the surface layer of the elastic layer on the surface from which the growth substrate is peeled off may be removed.

The electrical inspection device may comprise a pair of inspection heads, such that both surfaces of the inspection target can be inspected at the same time. Furthermore, the electrical inspection device according to the present invention may carry out relative positioning between the electrical inspection head and the measurement target by means of a drive mechanism that holds and moves the measurement target.

The anisotropic conductive sheet according to the present invention can be particularly suitably used as a probe assembly of an electrical inspection device that measures the electric characteristics between a plurality of measurement points on a printed-circuit board having a high wiring density. Additionally, the anisotropic conductive sheet according to the present invention can be used for a connection between a glass substrate and a flexible printed-circuit board. Furthermore, the anisotropic conductive sheet according to the present invention can be used for mounting electronic components such as an IC on a printed-circuit board or the like by having a configuration in which the CNT pillar comprises a metal portion formed from solder.

### General Interpretation of Terms

In understanding the scope of the present invention, the term “detect” as used herein to describe an operation or function carried out by a component, a section, a device or the like includes a component, a section, a device or the like that does not require physical detection, but rather includes determining, measuring, modeling, predicting or computing or the like to carry out the operation or function. The term “configured” as used herein to describe a component, section or part of a device includes hardware and/or software that is constructed and/or programmed to carry out the desired function. The terms of degree such as “substantially”, “about” and “approximately” as used herein mean an amount of deviation of the modified term such that the end result is not significantly changed.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Every feature which is unique from the prior art, alone or in combination with other features, also should be considered a separate description of further inventions by the applicant, including the structural and/or functional concepts embodied by such feature(s). Thus, the foregoing descriptions of the embodiments according to the present invention are provided for illustration only, and not for the purpose of limiting the invention as defined by the appended claims and their equivalents.

What is claimed is:

1. An anisotropic conductive sheet comprising:
an elastic layer having resin as a main component; and
a plurality of carbon nanotube (CNT) pillars that are formed from a CNT fiber bundle and penetrate the elastic layer in the thickness direction.

2. The anisotropic conductive sheet according to claim 1, wherein
a type A durometer hardness of the elastic layer is 40 or more and 80 or less.

3. The anisotropic conductive sheet according to claim 1, wherein
each of the plurality of CNT pillars has a metal portion forming an end surface thereof, and at least the metal portion protrudes from the elastic layer.

4. An electrical inspection head for measuring electric characteristics between a plurality of measurement points of a measurement target, the electrical inspection head comprising:
a measurement substrate having a plurality of electrode pads on a surface that opposes the measurement points of the measurement target; and
the anisotropic conductive sheet according to claim 1, laminated on a surface that opposes the measurement target of the measurement substrate.

5. An electrical inspection device comprising:
the electrical inspection head according to claim 4; and
a drive mechanism configured to perform relative positioning of the electrical inspection head with respect to the measurement target.

6. The anisotropic conductive sheet according to claim 2, wherein
each of the plurality of CNT pillars has a metal portion forming an end surface thereof, and at least the metal portion protrudes from the elastic layer.

7. An electrical inspection head for measuring electric characteristics between a plurality of measurement points of a measurement target, the electrical inspection head comprising:
a measurement substrate having a plurality of electrode pads on a surface that opposes the measurement points of the measurement target; and
the anisotropic conductive sheet according to claim 2, laminated on a surface that opposes the measurement target of the measurement substrate.

8. An electrical inspection head for measuring electric characteristics between a plurality of measurement points of a measurement target, the electrical inspection head comprising:
a measurement substrate having a plurality of electrode pads on a surface that opposes the measurement points of the measurement target; and
the anisotropic conductive sheet according to claim 3, laminated on a surface that opposes the measurement target of the measurement substrate.

9. An electrical inspection head for measuring electric characteristics between a plurality of measurement points of a measurement target, the electrical inspection head comprising:
a measurement substrate having a plurality of electrode pads on a surface that opposes the measurement points of the measurement target; and
the anisotropic conductive sheet according to claim 6, laminated on a surface that opposes the measurement target of the measurement substrate.

10. An electrical inspection device comprising:
the electrical inspection head according to claim 7; and
a drive mechanism configured to perform relative positioning of the electrical inspection head with respect to the measurement target.

11. An electrical inspection device comprising:
the electrical inspection head according to claim 8; and
a drive mechanism configured to perform relative positioning of the electrical inspection head with respect to the measurement target.

12. An electrical inspection device comprising:
the electrical inspection head according to claim 9; and
a drive mechanism configured to perform relative positioning of the electrical inspection head with respect to the measurement target.

13. A method for manufacturing an anisotropic conductive sheet, the method comprising:
growing a plurality of carbon nanotube (CNT) pillars formed from CNT fiber bundles by chemical vapor deposition by arranging a catalyst on the surface of a growth substrate; and
filling a space between the plurality of CNT pillars with a resin composition.

14. The method for manufacturing an anisotropic conductive sheet according to claim 13, further comprising:
removing at least one surface layer of an elastic layer formed from the resin composition.

15. The method for manufacturing an anisotropic conductive sheet according to claim 13, further comprising:
heat treating the plurality of CNT pillars.

16. The method for manufacturing an anisotropic conductive sheet according to claim 14, further comprising:
heat treating the plurality of CNT pillars.
